(19) United States
(12) Patent Application Publication
(10) Pub. No.: US 2026/0190919 A1
(43) Pub. Date: Jul. 2, 2026

(54) APPARATUS FOR PROCESSING SUBSTRATE

(71) Applicant: SEMES CO., LTD., Cheonan-si (KR)

(72) Inventors: Hyun Soo KIM, Cheonan-si (KR); Young Jun LEE, Cheonan-si (KR); Dong Hoon KANG, Bucheon-si (KR); Seung Hwan LEE, Cheonan-si (KR); Jin Ki SHIN, Cheonan-si (KR); Su Jin AHN, Suwon-si (KR); Kwang Soo KIM, Cheonan-si (KR); Sang Hyun PARK, Yongin-si (KR); Geon Yup LIM, Yongin-si (KR)

(21) Appl. No.: 19/369,520

(22) Filed: Oct. 27, 2025

(30) Foreign Application Priority Data
Dec. 26, 2024 (KR) 10-2024-0197000

(51) Int. Cl. H01L 21/67; G03F 7/16; H01L 21/677; H01L 21/687

(52) U.S. Cl. CPC H10P 72/0474; G03F 7/168; H10P 72/0431; H10P 72/0456; H10P 72/32; H10P 72/7602

(57) ABSTRACT

An apparatus for processing a substrate is provided, the apparatus including a heat treatment unit including a plurality of heat treatment chambers for heat-treating a substrate, a cooling unit including a first cooling chamber and a second cooling chamber for cooling the substrate, a liquid treatment unit for liquid-treating the substrate, and a transfer unit including a transfer robot for transferring the substrate between the heat treatment unit, the cooling unit, and the liquid treatment unit, wherein the plurality of heat treatment chambers, the first cooling chamber, and the second cooling chamber are disposed in a line, the first cooling chamber is disposed on one side of the plurality of heat treatment chambers, and the second cooling chamber is disposed between the plurality of heat treatment chambers.

### CROSS-REFERENCE TO RELATED APPLICATIONS

This application claims benefit of priority to Korean Patent Application No. 10-2024-0197000 filed Dec. 26, 2024 in the Korean Intellectual Property Office, the disclosure of which is incorporated herein by reference in its entirety.

### BACKGROUND

### 1. FIELD

The present disclosure relates to an apparatus for processing a substrate.

### 2. DESCRIPTION OF RELATED ART

A photolithography process in a semiconductor manufacturing process is a process of forming a desired pattern on a wafer. The photolithography process includes a coating process of forming a film by coating a photosensitive solution such as photoresist to a surface of a substrate, an exposure process of transferring a circuit pattern to a film formed on the substrate, and a development process of selectively removing the film formed on the substrate from the exposed region or a region opposite thereto.

In these processes, processing to heat or cool the substrate is performed. However, in a conventional apparatus for processing a substrate, a cooling unit for cooling the substrate was disposed on one side of the apparatus, particularly on one side of a heat treatment unit, so that a movement path of the substrate was inefficiently configured, and there was the problem of reduced efficiency of the overall substrate processing process.

### SUMMARY

An aspect of the present disclosure is to provide an apparatus for processing a substrate for efficiently improving a movement path of a transfer robot.

An aspect of the present disclosure is to provide an apparatus for processing a substrate that can improve the lifespan of a transfer robot by effectively reducing a movement distance of the transfer robot within a processing block, and reducing the possibility of damage thereto during substrate transfer.

An aspect of the present disclosure is to provide an apparatus for processing a substrate that can reduce the time required for a substrate processing process by shortening the time required for transferring the substrate, and improve process efficiency by increasing the number of substrates processed per unit time.

An object of the present disclosure is not limited to the above description. The object of the present disclosure will be understood from the entire contents of the present specification, and a person skilled in the art to which the present disclosure pertains will understand an additional object of the present disclosure without difficulty.

In order to achieve the above-described purpose, an aspect of the present disclosure is to provide an apparatus for processing a substrate as follows.

According to an aspect of the present disclosure, an apparatus for processing a substrate is provided, the apparatus including a heat treatment unit including a plurality of heat treatment chambers for heat-treating a substrate, a cooling unit including a first cooling chamber and a second cooling chamber for cooling the substrate, a liquid treatment unit for liquid-treating the substrate, and a transfer unit including a transfer robot for transferring the substrate between the heat treatment unit, the cooling unit, and the liquid treatment unit, wherein the plurality of heat treatment chambers, the first cooling chamber, and the second cooling chamber are disposed in a line, the first cooling chamber is disposed on one side of the plurality of heat treatment chambers, and the second cooling chamber is disposed between the plurality of heat treatment chambers.

According to an aspect of the present disclosure, an apparatus for processing a substrate is provided, the apparatus including a first heat treatment chamber and a second heat treatment chamber for heat-treating a substrate, a first cooling chamber and a second cooling chamber for cooling the substrate, a liquid treatment chamber for liquid-treating the substrate, and a transfer robot for transferring the substrate, wherein the first cooling chamber and the second cooling chamber, and the first heat treatment member and the second heat treatment member are disposed in a first line in the order of the first cooling chamber, the first heat treatment chamber, the second cooling chamber, and the second heat treatment chamber, the liquid treatment chamber is disposed in a second line, opposite to the first line, and the transfer robot is movably installed between the first line and the second line.

According to an aspect of the present disclosure, in an apparatus for processing a substrate including a plurality of substrate processing blocks stacked on each other in a vertical direction, wherein each of the plurality of substrate processing blocks includes a plurality of heat treatment chambers for heat-treating a substrate, a first cooling chamber and a second cooling chamber for cooling the substrate, a liquid treatment chamber for liquid-treating the substrate, and a transfer robot for transferring the substrate, wherein the plurality of heat treatment chambers, the first cooling chamber, and the second cooling chamber are disposed in a line, the first cooling chamber is disposed on one side of the plurality of heat treatment chambers, and the second cooling chamber is disposed between the plurality of heat treatment chambers.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view of an apparatus for processing a substrate according to an embodiment of the present disclosure;

FIG. 2 illustrates a plan view of an apparatus for processing a substrate according to the prior art;

FIG. 3 illustrates a plan view of an apparatus for processing a substrate according to an embodiment of the present disclosure;

FIG. 4A illustrates a movement path of a transfer robot in an apparatus for processing a substrate according to the prior art;

FIG. 4B illustrates an example of a movement path of a transfer robot in an apparatus for processing a substrate according to an embodiment of the present disclosure;

FIG. 5A illustrates a movement path of a transfer robot in an apparatus for processing a substrate according to the prior art;

FIG. 5B illustrates an example of a movement path of a transfer robot in an apparatus for processing a substrate according to an embodiment of the present disclosure;

FIG. 6A is a graph illustrating vibration displacement of a transfer robot in an apparatus for processing a substrate according to the prior art; and

FIG. 6B is a graph illustrating vibration displacement of a transfer robot in an apparatus for processing a substrate according to an embodiment of the present disclosure.

### DETAILED DESCRIPTION

Hereinafter, preferred embodiments will be described in detail so that those skilled in the art may easily practice the present disclosure with reference to the accompanying drawings. However, the embodiments of the present disclosure may be modified in various different forms, and the scope of the present disclosure is not limited to the embodiments described below.

In addition, the embodiments of the present disclosure are provided to more completely explain the present disclosure to a person having average knowledge in the relevant technical field.

The shape and size of elements in the drawing may be exaggerated for clearer explanation.

In describing preferred embodiments of the present disclosure in detail, and if it is determined that a detailed description of a related notice function or configuration may unnecessarily obscure the gist of the present disclosure, the detailed description thereof will be omitted. The terms to be described later are terms defined in consideration of functions in the present disclosure, which may vary according to the intention or custom of a user or operator. Therefore, the definition should be made based on the contents throughout this specification. The terminology used in the detailed description is only for describing the embodiments of the present disclosure and should in no way be limiting. Unless explicitly stated otherwise, singular forms of expression include plural forms.

In addition, in the present specification, terms such as ‘above,’ ‘upper portion,’ ‘upper surface,’ ‘below,’ ‘lower portion,’ ‘lower surface,’ ‘side surface’ and the like are based on the drawings, and may be changed depending on the direction in which the elements or components are actually disposed.

In addition, throughout the specification, when a part is said to be ‘connected’ to another part, it is not only ‘directly connected,’ but also ‘indirectly connected’ with other components therebetween. Further, ‘including’ a certain component means that other components may be further included, rather than excluding other components unless otherwise stated.

Hereinafter, the present disclosure will be described in detail through each embodiment or example of the present disclosure. It should be noted that each embodiment or example described in this specification is not limited to a single embodiment or example, and that combinations with other embodiments or examples are also possible. Therefore, the citation of claims in the scope of the patent claims is only an example of an embodiment, and the technical idea of the present disclosure should not be interpreted only as a combination with the cited claims, and combinations with various claims are also included in the scope of the technical idea of the present disclosure.

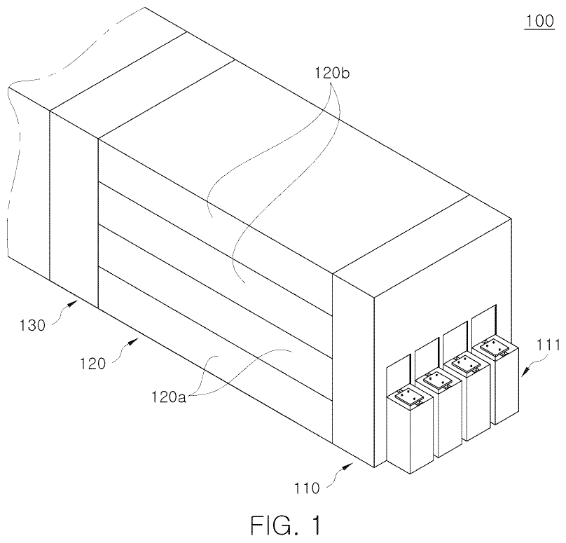

FIG. 1 schematically illustrates an apparatus for processing a substrate according to an embodiment of the present disclosure. An apparatus for processing a substrate 100 may include an index module 110, a substrate processing module 120, and an interface module 130.

In an embodiment, the index module 110, the substrate processing module 120, and the interface module 130 may be sequentially disposed in a row as illustrated in FIG. 1.

The index module 110 may include one or more load ports 111. A container for accommodating a substrate may be placed on the load port 111. The container may be, for example, a Front Open Unified Pod (FOUP).

The container may be provided to the load port 111 by a transfer means such as an overhead hoist transport (OHT), a conveyor, or a transfer vehicle, or by an operator.

The index module 110 may transfer the substrate between the load port 111 and the substrate processing module 120.

The substrate processing module 120 may perform a coating process or a development process on the substrate. The substrate processing module 120 may include one or more coating blocks 120a and one or more developing blocks 120b.

The coating block 120a and the developing block 120b may be disposed to be stacked on each other in a vertical direction. In the embodiment illustrated in FIG. 1, the coating block 120a may be disposed on first and second layers of the substrate processing module 120, and the developing block 120b may be disposed on third and fourth layers.

The coating block 20a may perform a coating process on a substrate before an exposure process is performed.

The developing block 120b may perform a developing process on a substrate after an exposure process has been performed.

The interface module 130 may transfer the substrate between the substrate processing module 120 and an exposure device (not shown).

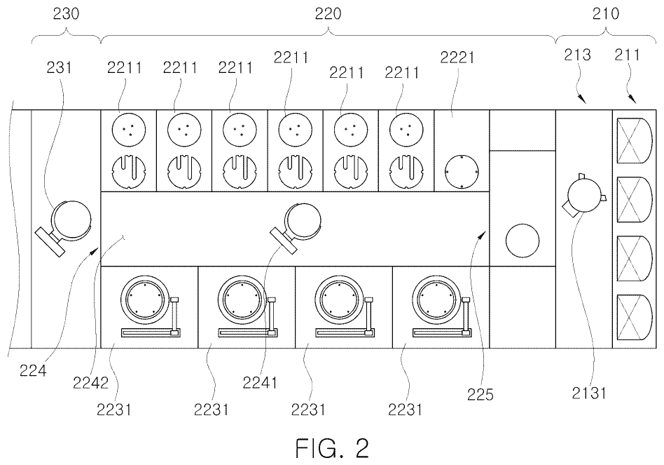

FIG. 2 is a plan view of an apparatus for processing a substrate according to the prior art. The apparatus for processing a substrate according to the prior art also has the same structure as that illustrated in FIG. 1. That is, in the apparatus for processing a substrate according to the prior art, an index module 210, a substrate processing module 220, and an interface module 230 are sequentially disposed in a row.

Referring to a plan view of FIG. 2, the index module 210 has a load port 211 and an index chamber 213. An index robot 2131 is disposed in the index chamber 213 to transfer a substrate between the load port 211 and the substrate processing module 220.

In addition, the interface module 230 includes an auxiliary transfer robot 231 that transfers the substrate between the substrate processing module 220 and an external exposure device.

The substrate processing module 220 is disposed between the index module 210 and the interface module 230. The substrate processing module 220 performs coating or developing processing on the substrate.

The substrate processing module 220 includes a buffer 225 receiving the substrate from the index robot 2131.

The substrate processing module 220 further includes a plurality of heat treatment chambers 2211, a cooling chamber 2221, and a plurality of liquid treatment chambers 2231. The plurality of liquid treatment chambers 2231 may be one of a coating chamber or a developing chamber.

The substrate processing module 220 further includes a transfer robot 2241 for transferring the substrate between the plurality of heat treatment chambers 2211, the cooling chamber 2221, and the plurality of liquid treatment chambers 2231. The transfer robot 2241 moves in a transfer space provided within the transfer chamber 2242 and transfers the substrate.

As illustrated in FIG. 2, in the apparatus for processing a substrate according to the prior art, a cooling chamber 2221 is disposed on one side of the plurality of heat treatment chambers 2211. Due to such layout, whenever a cooling treatment of a substrate is required within the substrate processing module 220, since the substrate should be transferred to the cooling chamber 2221 disposed on one side of the plurality of heat treatment chambers 2211, there was a problem in that the total movement path of the transfer robot 2241 increased, and the total processing time increased, thereby reducing the substrate processing efficiency.

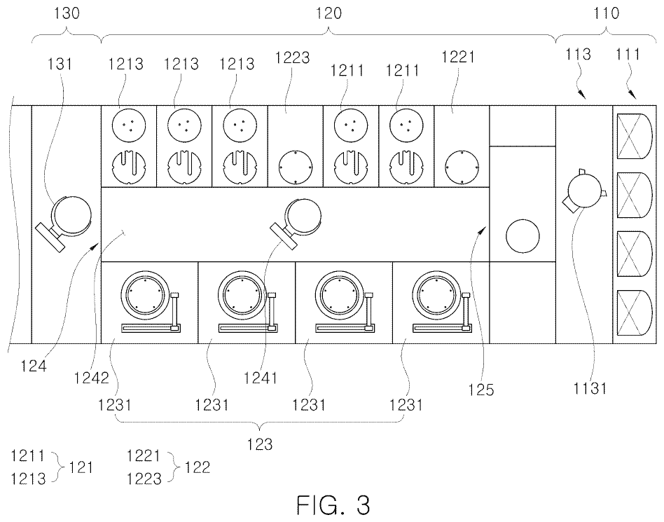

Hereinafter, an apparatus for processing a substrate according to an embodiment of the present disclosure is described in detail with reference to FIG. 3. FIG. 3 illustrates a plan view of an apparatus for processing a substrate according to an embodiment of the present disclosure.

As illustrated in FIG. 3, an index module 110, a substrate processing module 120, and an interface module 130 may be sequentially disposed in a row.

The index module 110 may include one or more load ports 111 and index chambers 113.

A container for accommodating a substrate may be placed in the load port 111. The container can be, for example, a FOUP.

An index robot 1131 for transferring a substrate between the load port 111 and the substrate processing module 120 may be disposed in the index chamber 113.

The interface module 130 may include an auxiliary transfer robot 131 for transferring the substrate between the substrate processing module 120 and an external exposure device.

The auxiliary transfer robot 131 may include a transfer mechanism for transferring substrates between a plurality of stacked substrate processing blocks. For example, the auxiliary transfer robot 131 may transfer a coated substrate from a coating block 120a to a developing block 120b.

The substrate processing module 120 may be disposed between the index module 110 and the interface module 130. The substrate processing module 120 may perform a coating or developing treatment on the substrate. In the plan view illustrated in FIG. 3, the substrate processing module 120 may be one of the coating block 120a or the developing block 120b.

The substrate processing module 120 may include a heat treatment unit 121, a cooling unit 122, a liquid treatment unit 123, a transfer unit 124, and a buffer unit 125.

The heat treatment unit 121 may include a plurality of heat treatment chambers 1211 and 1213 for heat-treating a substrate. The plurality of heat treatment chambers 1211 and 1213 may include a first heat treatment chamber 1211 and a second heat treatment chamber 1213.

The cooling unit 122 may include a plurality of cooling chambers 1221 and 1223 for cooling the substrate. The plurality of cooling chambers 1221 and 1223 may include a first cooling chamber 1221 and a second cooling chamber 1223 disposed to be spaced apart from each other.

A plurality of heat treatment chambers 1211 and 1213 and a plurality of cooling chambers 1221 and 1223 may be disposed in a line in a row.

The first cooling chamber 1221 may be disposed on one side of the plurality of heat treatment chambers 1211 and 1213. For example, the first cooling chamber 1221 may be disposed on a right side of the plurality of heat treatment chambers 1211 and 1213, in contact with a portion of the buffer unit 125.

The second cooling chamber 1223 may be disposed between the plurality of heat treatment chambers 1211 and 1213. For example, the second cooling chamber 1223 may be disposed between the heat treatment chambers 1211 and 1213, disposed in a row.

The first heat treatment chamber 1211 may be disposed between the first cooling chamber 1221 and the second cooling chamber 1223.

That is, the first cooling chamber 1221 and the second cooling chamber 1223, and the first heat treatment chamber 1211 and the second heat treatment chamber 1213 may be disposed in a line in a row in the order of the first cooling chamber 1221, the first heat treatment chamber 1211, the second cooling chamber 1223, and the second heat treatment chamber 1213.

The liquid treatment unit 123 may include a plurality of liquid treatment chambers 1231 for liquid-treating a substrate. The plurality of liquid treatment chambers 1231 may be disposed in a line, different from a line in which the plurality of heat treatment chambers 1211 and 1213 and the plurality of cooling chambers 1221 and 1223 are disposed in a row.

In the coating block 120a, the plurality of liquid treatment chambers 1231 may be a plurality of coating chambers performing a coating treatment on the substrate.

In the developing block 120b, the plurality of liquid treatment chambers 1231 may be a plurality of developing chambers performing a developing treatment on the substrate.

The transfer unit 124 may include a transfer robot 1241 and a transfer chamber 1242.

The transfer chamber 1242 may provide a transfer space in which a transfer robot 1241 transferring a substrate moves. The transfer chamber 1242 may be disposed vertically between the heat treatment unit 121 and the cooling unit 122, and the liquid treatment unit 123, and horizontally between the buffer unit 125 and the interface module 130.

A plurality of liquid treatment chambers 1231 may be disposed in another line, opposite to the line in which a plurality of heat treatment chambers 1211 and 1213 and a plurality of cooling chambers 1221 and 1223 are disposed with a transfer chamber 1242 interposed therebetween.

That is, the transfer robot 1241 may be movably installed between a line in which a plurality of heat treatment chambers 1211 and 1213 and a plurality of cooling chambers 1221 and 1223 are disposed and a line in which a plurality of liquid treatment chambers 1231 are disposed.

The buffer unit 125 may store the substrate received from the index module 110, and transfer the substrate to the transfer robot 1241.

The transfer robot 1241 may transfer the substrate between the heat treatment unit 121, the cooling unit 122, the liquid treatment unit 123, the buffer unit 125, and the interface module 130.

The transfer robot 1241 may transfer the substrate to any one of the heat treatment unit 121, the cooling unit 122, and the liquid treatment unit 123 according to a transfer flow determined based on a processing order of the substrate.

The substrate may be transferred in a substrate movement direction from upstream to downstream according to the transfer flow.

For example, when the substrate is moved from the buffer unit 125 toward the interface module 130 based on a preset processing order, the upstream of the substrate movement direction may be to the right and the downstream thereof may be to the left.

Conversely, when the substrate is moved from the interface module 130 toward the buffer unit 125 based on a preset processing order, the upstream of the substrate movement direction may be to the left and the downstream thereof may be to the right.

The processing order of the substrate may include a first cooling treatment order and a second cooling treatment order. The second cooling treatment order may be performed subsequently to the first cooling treatment.

The transfer robot 124 may transfer the substrate to a cooling chamber located upstream in the substrate movement direction among the first cooling chamber 1221 and the second cooling chamber 1223 in the first cooling treatment order.

In addition, the transfer robot 124 may transfer the substrate to a cooling chamber located downstream in the substrate movement direction among the first cooling chamber 1221 and the second cooling chamber 1223 in the second cooling treatment order.

For example, when the substrate movement direction is from the right (upstream) to the left (downstream) as illustrated in FIG. 3, the transfer robot 1241 may transfer the substrate to the first cooling chamber 1221 in the first cooling treatment order, and transfer the substrate to the second cooling chamber 1223 in the second cooling treatment order.

For another example, when the substrate movement direction is from the left (upstream) to the right (downstream) as illustrated in FIG. 3, the transfer robot 1241 may transfer the substrate to the second cooling chamber 1223 in the first cooling treatment order, and transfer the substrate to the first cooling chamber 1221 in the second cooling treatment order.

In the coating block 120a, a substrate may be transferred according to a first transfer flow determined based on a substrate coating treatment order. The substrate movement direction according to the first transfer flow may be set from right (upstream) to left (downstream).

In this case, the first cooling chamber 1221 may be located upstream of the second cooling chamber 1223 in the substrate movement direction. In addition, the first heat treatment chamber 1211 may be located upstream of the second heat treatment chamber 1213 in the substrate movement direction.

The plurality of liquid treatment chambers 1231 may include a plurality of coating chambers. The plurality of coating chambers may include a first coating chamber and a second coating chamber.

In the first coating chamber, an anti-reflection film may be applied to the surface of the substrate, and in the second coating chamber, a photoresist liquid may be applied to the surface of the substrate.

The second coating chamber may be disposed downstream of the first coating chamber in the substrate movement direction.

The transfer robot 1241 may transfer the substrate in the order of the first cooling chamber 1221, the first coating chamber, the first heat treatment chamber 1211, the second cooling chamber 1223, the second coating chamber, and the second heat treatment chamber 1213.

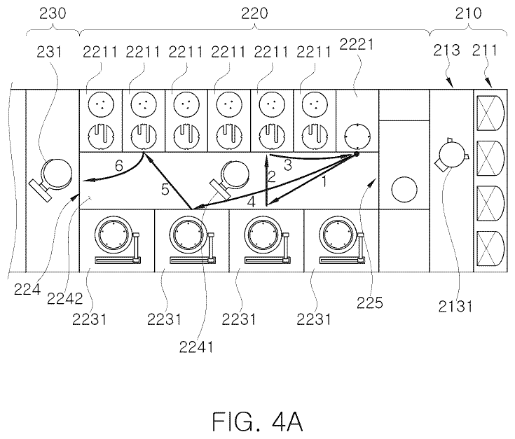

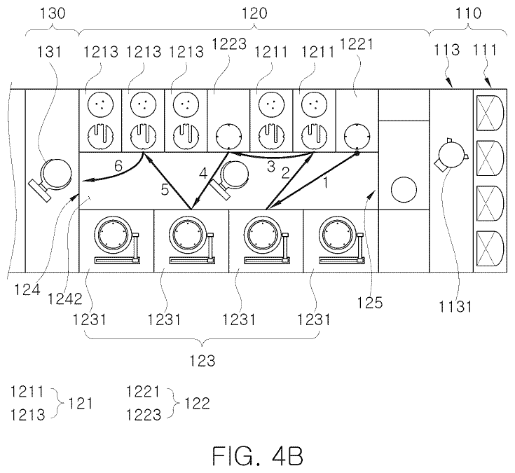

FIG. 4A illustrates a movement path of a transfer robot of a coating block in an apparatus for processing a substrate according to the prior art, and FIG. 4B illustrates a movement path of a transfer robot of a coating block in an apparatus for processing a substrate according to an embodiment of the present disclosure. The movement path of the transfer robot is indicated by a bold arrow, and the numbers written next to the bold arrows indicate a movement order of the transfer robot.

FIGS. 4A and 4B illustrate an example of the movement path of the transfer robot when a processing order of the substrate in the coating block is set to the order of a first cooling treatment—a first coating treatment—a first heat treatment—a second cooling treatment—a second coating treatment—a second heat treatment.

In addition, FIGS. 4A and 4B illustrate an example in which the substrate movement direction is from right (upstream) to left(downstream) according to a transfer flow determined based on the processing order of the substrate in the coating block.

In the apparatus for processing a substrate according to the prior art, as illustrated in FIG. 4A, a transfer robot 2241 transfers a substrate to a cooling chamber 2221 in a first cooling treatment order, and then transfers the substrate to the cooling chamber 2221 again in a second cooling treatment order performed thereafter. Since the cooling chamber 2221 is disposed on one side of the plurality of heat treatment chambers 2211 in contact with the buffer 225, there was a problem that the transfer robot 2241 had to move along an inefficient path.

In comparison, referring to FIG. 4B, in the apparatus for processing a substrate according to an embodiment of the present disclosure, a transfer robot 1241 transfers a substrate to a first cooling chamber 1221 in a first cooling treatment order, and then transfers the substrate to a second cooling chamber 1223 located downstream of the first cooling chamber 1221 in the substrate movement direction in a second cooling treatment order performed thereafter.

Comparing FIGS. 4A and 4B, it can be seen that the movement path of the transfer robot 1241 may be efficiently formed in an internal layout of the device as in FIG. 4B. According to the present disclosure, the lifespan of the transfer robot may be improved by reducing the movement path of the transfer robot, and the possibility of substrate damage may be reduced.

In addition, the total time required to perform the same processing process is reduced, which can have the effect of improving the number of substrates processed per unit time, i.e., processing efficiency.

Meanwhile, in the developing block 120b, the substrate may be transferred according to a second transfer flow determined based on a substrate developing processing order. A substrate movement direction along the second transfer flow may be set from left (upstream) to right (downstream). The substrate movement direction along the second transfer flow may be opposite to the direction of movement of the substrate along the first transfer flow.

In this case, the first cooling chamber 1221 may be located downstream of the second cooling chamber 1223 in the substrate movement direction. In addition, the first heat treatment chamber 1211 may be located downstream of the second heat treatment chamber 1213 in the substrate movement direction.

The plurality of liquid treatment chambers 1231 may include a plurality of developing chambers.

The transfer robot 1241 may transfer the substrate in the order of the second heat treatment chamber 1213, the second cooling chamber 1223, any one of the plurality of developing chambers, the first heat treatment chamber 1211, and the first cooling chamber 1221.

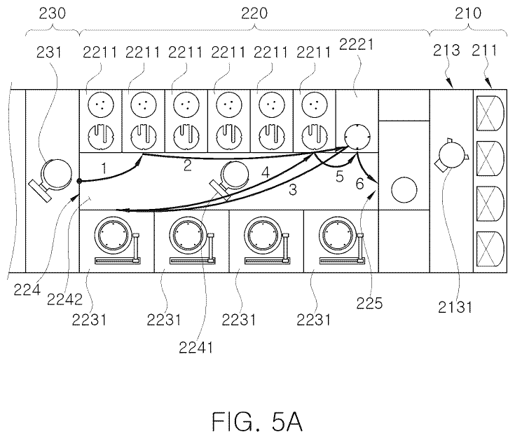

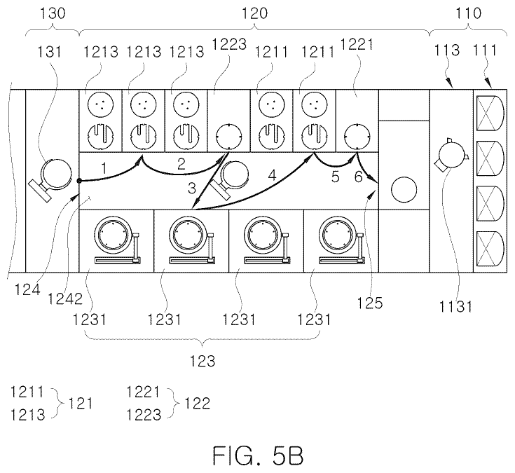

FIG. 5A illustrates a movement path of a transfer robot of a developing block in an apparatus for processing a substrate according to the prior art, and FIG. 5B illustrates a movement path of a transfer robot of a developing block in an apparatus for processing a substrate according to an embodiment of the present disclosure. The movement path of the transfer robot is indicated by a bold arrow, and the numbers written next to the bold arrows indicate a movement order of the transfer robot.

FIGS. 5A and 5B illustrate an example of a movement path of a transfer robot when a processing order of a substrate in a developing block is set to the order of a first heat treatment—a first cooling treatment—a developing treatment-a second heat treatment—a second cooling treatment.

In addition, FIGS. 5A and 5B illustrate an example in which the substrate movement direction is from left (upstream) to right (downstream) according to a transfer flow determined based on the processing order of the substrate in the developing block.

In the apparatus for processing a substrate according to the prior art, as illustrated in FIG. 5A, a transfer robot 2241 transfers a substrate to a cooling chamber 2221 in a first cooling treatment order, and then transfers the substrate to the cooling chamber 2221 again in a second cooling treatment order performed thereafter. Since the cooling chamber 2221 is disposed on one side of the plurality of heat treatment chambers 2211 in contact with the buffer 225, there was a problem that the transfer robot 2241 had to move along an inefficient path, as in the case of FIG. 4A.

In comparison, referring to FIG. 5B, in an apparatus for processing a substrate according to an embodiment of the present disclosure, a transfer robot 1241 transfers a substrate to a second cooling chamber 1223 in a first cooling treatment order, and then transfers the substrate to a first cooling chamber 1221 located downstream of the second cooling chamber 1223 in the substrate movement direction in a second cooling treatment order performed thereafter.

Comparing FIGS. 5A and 5B, it can be seen that the movement path of the transfer robot 1241 may be efficiently formed in an internal layout of the device as in FIG. 5B.

According to the present disclosure, the lifespan of the transfer robot may be improved by reducing the movement path of the transfer robot, and the possibility of substrate damage may be reduced.

In addition, the total time required to perform the same processing process is reduced, which can have the effect of improving the number of substrates processed per unit time, i.e., processing efficiency.

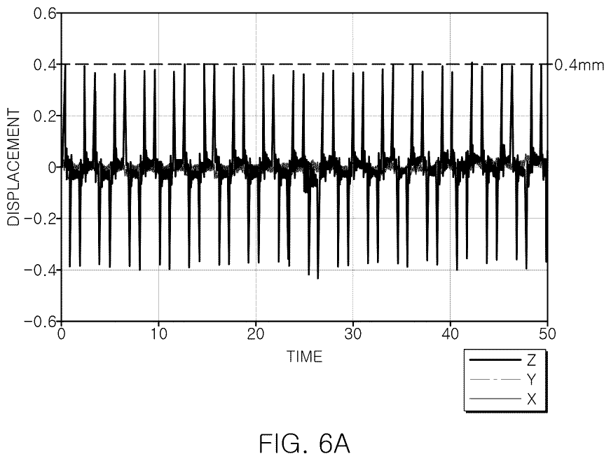

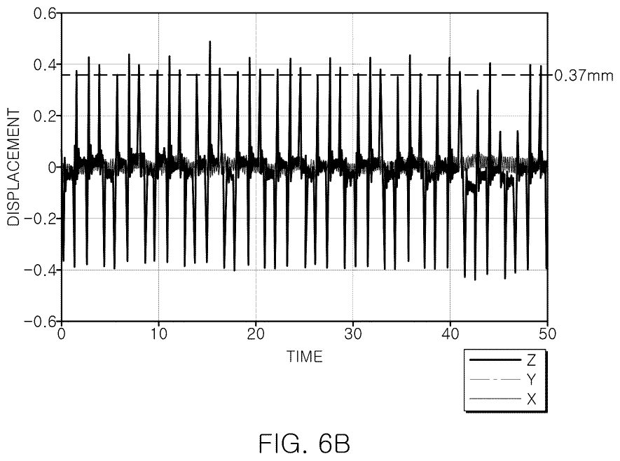

FIG. 6A is a graph illustrating vibration displacement of a frame that occurs while a transfer robot transfers a substrate in an apparatus for processing a substrate according to the prior art, and FIG. 6B is a graph illustrating vibration displacement of a frame that occurs while a transfer robot transfers a substrate in an apparatus for processing a substrate according to an embodiment of the present disclosure.

Comparing FIGS. 6A and 6B, it was confirmed that the vibration displacement of the frame that occurs while the transfer robot according to an embodiment of the present disclosure transfers the substrate is relatively reduced compared to the apparatus for processing a substrate according to the prior art.

In the several embodiments provided in the present application, it should be understood that the disclosed devices and methods may be implemented in other manners. For example, the device embodiments described above are merely illustrative, and for example, the division of the unit is only a logical function division, and in actual implementation, other division methods may be provided. For example, a plurality of units or the assembly may be coupled or integrated into one other system, or some features may be ignored or not performed. On the other hand, the couplings or direct couplings or mutual communication connections illustrated or discussed may be indirect couplings or communication connections through some interface, device or unit, and may be electrical, mechanical or other types.

The units described above as separate components may be physically separate, and the components represented as units may or may not be physical units, i.e., located in one location or distributed across multiple network units. Depending on actual demand, a portion or all of the units can be selected to achieve the purpose of the present embodiment.

That is, each functional unit in each embodiment of the present application may be integrated into a single processing unit, each unit may exist alone, or two or more units may be integrated into a single unit.

As set forth above, according to the present disclosure, an apparatus for processing a substrate that can improve a movement path of a transfer robot may be provided.

According to the present disclosure, in an embodiment, an apparatus for processing a substrate that can improve the lifespan of a transfer robot by effectively reducing a movement distance of the transfer robot within a processing block, and reduce the possibility of damage during substrate transfer may be provided.

According to the present disclosure, in an embodiment, an apparatus for processing a substrate that can reduce the time required for a substrate processing process by shortening the time required for transferring the substrate, and improve process efficiency by increasing the number of substrates processed per unit time, may be provided.

While example embodiments have been illustrated and described above, it will be apparent to those skilled in the art that modifications and variations could be made without departing from the scope of the present disclosure as defined by the appended claims.

What is claimed is:

1. An apparatus for processing a substrate, comprising:
a heat treatment unit including a plurality of heat treatment chambers for heat-treating a substrate;
a cooling unit including a first cooling chamber and a second cooling chamber for cooling the substrate;
a liquid treatment unit for liquid-treating the substrate; and
a transfer unit including a transfer robot for transferring the substrate between the heat treatment unit, the cooling unit, and the liquid treatment unit,
wherein the plurality of heat treatment chambers, the first cooling chamber, and the second cooling chamber are disposed in a line,
the first cooling chamber is disposed on one side of the plurality of heat treatment chambers, and
the second cooling chamber is disposed between the plurality of heat treatment chambers.

2. The apparatus for processing a substrate of claim 1, wherein the transfer unit further comprises a transfer chamber providing a transfer space in which the transfer robot moves,
wherein the liquid treatment unit comprises a plurality of liquid treatment chambers disposed in a row in another line, opposite to the line with the transfer chamber interposed therebetween.

3. The apparatus for processing a substrate of claim 2, wherein the transfer robot transfers the substrate to any one of the heat treatment unit, the cooling unit, and the liquid treatment unit according to a transfer flow determined based on a processing order of the substrate, and
the substrate is transferred in a substrate movement direction from upstream to downstream according to the transfer flow.

4. The apparatus for processing a substrate of claim 3, wherein the processing order of the substrate comprises a first cooling treatment order and a second cooling treatment order performed subsequently to the first cooling treatment,
the transfer robot transfers the substrate to a cooling chamber located upstream in the substrate movement direction among the first cooling chamber and the second cooling chamber in the first cooling treatment order, and
the transfer robot transfers the substrate to a cooling chamber located downstream in the substrate movement direction among the first cooling chamber and the second cooling chamber in the second cooling treatment order.

5. The apparatus for processing a substrate of claim 4, wherein the plurality of liquid treatment chambers comprise a plurality of coating chambers performing a coating treatment on the substrate.

6. The apparatus for processing a substrate of claim 5, wherein the first cooling chamber is located upstream of the second cooling chamber in the substrate movement direction.

7. The apparatus for processing a substrate of claim 6, wherein the plurality of heat treatment chambers comprise a first heat treatment chamber disposed between the first cooling chamber and the second cooling chamber; and a second heat treatment chamber disposed downstream of the second cooling chamber in the substrate movement direction,
the plurality of coating chambers include a first coating chamber; and a second coating chamber disposed downstream of the first coating chamber in the substrate movement direction, and
the transfer robot transfers the substrate in the order of the first cooling chamber, the first coating chamber, the first heat treatment chamber, the second cooling chamber, the second coating chamber, and the second heat treatment chamber.

8. The apparatus for processing a substrate of claim 4, wherein the plurality of liquid treatment chambers comprise a plurality of developing chambers performing a developing treatment on the substrate.

9. The apparatus for processing a substrate of claim 8, wherein the first cooling chamber is located downstream of the second cooling chamber in the substrate movement direction.

10. The apparatus for processing a substrate of claim 9, wherein the plurality of heat treatment chambers comprise a first heat treatment chamber disposed between the first cooling chamber and the second cooling chamber; and a second heat treatment chamber disposed upstream of the second cooling chamber in the substrate movement direction, and
the transfer robot transfers the substrate in the order of the second heat treatment chamber, the second cooling chamber, any one of the plurality of developing chambers, the first heat treatment chamber, and the first cooling chamber.

11. An apparatus for processing a substrate, comprising:
a first heat treatment chamber and a second heat treatment chamber for heat-treating a substrate;
a first cooling chamber and a second cooling chamber for cooling the substrate;
a liquid treatment chamber for liquid-treating the substrate; and
a transfer robot for transferring the substrate,
wherein the first cooling chamber and the second cooling chamber, and the first heat treatment chamber and the second heat treatment chamber are disposed in a first line in the order of the first cooling chamber, the first heat treatment chamber, the second cooling chamber, and the second heat treatment chamber,
the liquid treatment chamber is disposed in a second line, opposite to the first line, and
the transfer robot is movably installed between the first line and the second line.

12. The apparatus for processing a substrate of claim 11, wherein the transfer robot transfers the substrate according to a transfer flow determined based on a processing order of the substrate, and
the substrate is transferred in a substrate movement direction from upstream to downstream according to the transfer flow.

13. The apparatus for processing a substrate of claim 11, wherein the processing order of the substrate comprises a first cooling treatment order and a second cooling treatment order performed subsequently to the first cooling treatment,
wherein the transfer robot transfers the substrate to a cooling chamber located upstream in the substrate movement direction among the first cooling chamber and the second cooling chamber in the first cooling treatment order, and
transfers the substrate to a cooling chamber located downstream in the substrate movement direction among the first cooling chamber and the second cooling chamber in the second cooling treatment order.

14. The apparatus for processing a substrate of claim 13, wherein the liquid treatment chamber comprises a coating chamber performing a coating treatment on the substrate.

15. The apparatus for processing a substrate of claim 14, wherein the first cooling chamber is located upstream of the second cooling chamber in the substrate movement direction.

16. The apparatus for processing a substrate of claim 14, wherein the liquid treatment chamber comprises a developing chamber performing a developing treatment on the substrate.

17. The apparatus for processing a substrate of claim 16, wherein the first cooling chamber is located downstream of the second cooling chamber in the substate movement direction.

18. In an apparatus for processing a substrate including a plurality of substrate processing blocks stacked on each other in a vertical direction,
wherein each of the plurality of substrate processing blocks comprises:
a plurality of heat treatment chambers for heat-treating a substrate;
a first cooling chamber and a second cooling chamber for cooling the substrate;
a liquid treatment chamber for liquid-treating the substrate; and
a transfer robot for transferring the substrate,
wherein the plurality of heat treatment chambers, the first cooling chamber, and the second cooling chamber are disposed in a line,
the first cooling chamber is disposed on one side of the plurality of heat treatment chambers, and
the second cooling chamber is disposed between the plurality of heat treatment chambers.

19. The apparatus for processing a substrate of claim 18, wherein the plurality of substrate processing blocks comprise
one or more coating blocks including a coating chamber for performing a coating treatment on the substrate as the liquid treatment chamber, wherein the substrate is transferred according to a first transfer flow determined based on a coating treatment order of the substrate; and
one or more developing blocks including a developing chamber for performing a developing treatment on the substrate as the liquid treatment chamber, wherein the substrate is transferred according to a second transfer flow determined based on a developing treatment order of the substrate.

20. The apparatus for processing a substrate of claim 19, further comprising:
a transfer mechanism for transferring the substrate between the plurality of substrate processing blocks,
wherein the transfer mechanism transfers a coated substrate from the coating block to the developing block, and
a substrate movement direction according to the first transfer flow and a substrate movement direction according to the second transfer flow in the developing block are opposite to each other.
